(19) United States
(12) Patent Application Publication
(10) Pub. No.: US 2026/0051858 A1
(43) Pub. Date: Feb. 19, 2026

(54) Signal detection apparatus and re-driver

(71) Applicants: Analogix (Suzhou) Semiconductor Co., LTD., Suzhou (CN); ANALOGIX INTERNATIONAL LLC

(72) Inventors: Shi ZUO, Suzhou (CN); Liang XUE, Suzhou (CN); Zhongyuan HOU, Suzhou (CN)

(21) Appl. No.: 19/199,251

(22) Filed: May 5, 2025

Related U.S. Application Data
(63) Continuation of application No. PCT/CN2023/112626, filed on Aug. 11, 2023.

(30) Foreign Application Priority Data
Aug. 2, 2023 (CN) 202310967289.3

(51) Int. Cl. H03F 3/04; H03F 1/02

(52) U.S. Cl. CPC H03F 3/04; H03F 1/0211

(57) ABSTRACT

This application provides a signal detection apparatus and a re-driver. The signal detection apparatus includes an amplification unit and a comparison unit. The amplification unit includes a first amplification component and a second amplification component. The first amplification component is configured to amplify a first differential signal pair to obtain a first differential amplified signal pair. The second amplification component is configured to amplify a reference signal pair. A third end of the amplification unit is used for outputting the first differential amplified signal pair and the reference amplified signal pair. The first amplification component and the second amplification component are the same. The comparison unit is electrically connected with the third end of the amplification unit, and is configured to compare the first target signal and a reference threshold and compare the second target signal and the reference threshold, and output a comparison result.

### CROSS-REFERENCE TO RELATED APPLICATIONS

The application is a continuation of PCT Application No. PCT/CN2023/112626 filed Aug. 11, 2023, which claims priority to Chinese Patent Application No. 2023109672893, filed on Aug. 2, 2023, and entitled “A SIGNAL DETECTION APPARATUS AND A RE-DRIVER”, the entire contents of which are incorporated herein by reference.

### TECHNICAL FIELD

This application relates to the field of wired communication integrated circuits, and more particularly, relates to a signal detection apparatus and a re-driver.

### BACKGROUND

A re-driver can enhance signal integrity of a long-distance channel and reduce balance pressure of a receiver in a high-speed serial circuit, and has been widely applied in the field of wired communication in consumer electronics. In the actual use of the circuit, the re-driver needs to detect upstream transmitted signals in real time to judge whether to activate a main circuit function, in order to achieve the purposes of reducing power consumption and improving product life. High-speed signals received by the re-driver are transmitted through a long channel, causing that the amplitude of the high-speed signals is attenuated to a great degree, and thus, a signal detector needs to distinguish small-amplitude valid signals from transmission noise, which limits a detection threshold range. If the detection threshold is high, the valid signals cannot wake up a main circuit of the re-driver; and if the detection threshold is low and less than the magnitude of the transmission noise, the main circuit of the re-driver will be falsely activated, resulting in a waste of power consumption. However, the performance of the existing structural high-speed signal detector is influenced by variations in process, voltage, and temperature (PVT), and the detection threshold of the signal detector fluctuates within a wide range, exceeding the specified range, which can result in circuit functionality failure.

Thus, there is an urgent need for a method to solve the problem that the existing speed signal detector is influenced by the process, voltage, and temperature, resulting in inaccurate signal detection results.

### SUMMARY

According to one aspect of this application, a signal detection apparatus is provided, and includes an amplification unit and a comparison unit. A first end of the amplification unit is used for inputting a first differential signal pair, and a second end of the amplification unit is used for inputting a reference signal pair. The amplification unit includes a first amplification component and a second amplification component. The first amplification component is configured to amplify the first differential signal pair to obtain a first differential amplified signal pair. The second amplification component is configured to amplify the reference signal pair to obtain a reference amplified signal pair. A third end of the amplification unit is used for outputting the first differential amplified signal pair and the reference amplified signal pair. The first differential amplified signal pair includes a first target signal and a second target signal. The reference amplified signal pair includes a first target reference signal and a second target reference signal. The first amplification component and the second amplification component are the same. The comparison unit is electrically connected with the third end of the amplification unit, and is configured to compare the first target signal and a reference threshold and compare the second target signal and the reference threshold, and output a comparison result, where the reference threshold is a difference value between the first target reference signal and the second target reference signal.

Optionally, the first amplification component and the second amplification component both include a first switching device, a second switching device, a third switching device, a first impedance, and a second impedance. The second switching device and the third switching device are the same. A first end of the first switching device is used for inputting a first control voltage, and a second end of the first switching device is respectively electrically connected with a third end of the second switching device and a third end of the third switching device. A third end of the first switching device is connected with a ground end, a second end of the second switching device is electrically connected with a first end of the first impedance, and a second end of the third switching device is electrically connected with a first end of the second impedance. A second end of the first impedance is electrically connected with a second end of the second impedance. A first end of the second switching device and a first end of the third switching device of the first amplification component are used for inputting the first differential signal pair. A first end of the second switching device and a first end of the third switching device of the second amplification component are used for inputting the reference signal pair. The second end of the second switching device and the second end of the third switching device of the first amplification component are used for outputting the first differential amplified signal pair, and the second end of the second switching device and the second end of the third switching device of the second amplification component are used for outputting the reference amplified signal pair.

Optionally, the first switching device, the second switching device, and the third switching device are N-Channel Metal Oxide Semiconductor (NMOS) tubes, the first impedance and the second impedance are resistors, each of the first end of the first switching device, the first end of the second switching device, and the first end of the third switching device is a grid of the NMOS tube, each of the second end of the first switching device, the second end of the second switching device, and the second end of the third switching device is a drain of the NMOS tube, and each of the third end of the first switching device, the third end of the second switching device, and the third end of the third switching device is a source of the NMOS tube.

Optionally, the comparison unit includes a fourth switching device, a fifth switching device, a sixth switching device, a seventh switching device, an eighth switching device, a ninth switching device, a tenth switching device, an eleventh switching device, a twelfth switching device, a third impedance, a fourth impedance, a fifth impedance, a sixth impedance, and an inverter; the fourth switching device, the fifth switching device, the sixth switching device, and the seventh switching device are the same; the eighth switching device and the ninth switching device are the same; a first end of the fourth switching device and a first end of the fifth switching device are used for inputting the first differential amplified signal pair; a second end of the fourth switching device is respectively electrically connected with a second end of the fifth switching device, a first end and a second end of the eighth switching device, and a first end of the third impedance; a second end of the third impedance is respectively electrically connected with a first end of the fourth impedance and a first end of the ninth switching device; a third end of the eighth switching device is respectively electrically connected with a second end of the fourth impedance, a third end of the ninth switching device, and a third end of the tenth switching device; a first end of the sixth switching device and a first end of the seventh switching device are used for inputting the reference amplified signal pair; a second end of the sixth switching device is respectively electrically connected with a second end of the seventh switching device, a second end of the ninth switching device, and a first end of the tenth switching device; a third end of the fourth switching device is respectively electrically connected with a third end of the fifth switching device, a third end of the sixth switching device, a third end of the seventh switching device, a second end of the eleventh switching device, and a first end of the fifth impedance; a first end of the eleventh switching device and a first end of the twelfth switching device are used for inputting a second control voltage; a third end of the eleventh switching device, a second end of the fifth impedance, a third end of the twelfth switching device, and a second end of the sixth impedance are connected with the ground end, a second end of the twelfth switching device is respectively electrically connected with a second end of the tenth switching device, a first end of the sixth impedance, and a first end of the inverter, and a second end of the inverter is used for outputting the comparison result.

Optionally, the eighth switching device, the ninth switching device, and the tenth switching device are P-Channel Metal Oxide Semiconductor (PMOS) tubes, the fourth switching device, the fifth switching device, the sixth switching device, the seventh switching device, the eleventh switching device, and the twelfth switching device are NMOS tubes, the third impedance is a resistor, and the fourth impedance, the fifth impedance, and the sixth impedance are capacitors; each of a first end of the eighth switching device, the first end of the ninth switching device, and the first end of the tenth switching device is a grid of the PMOS tube, each of the second end of the eighth switching device, the second end of the ninth switching device, and the second end of the tenth switching device is a drain of the PMOS tube, and each of the third end of the eighth switching device, the third end of the ninth switching device, and a third end of the tenth switching device is a source of the PMOS tube; each of the first end of the fourth switching device, the first end of the fifth switching device, the first end of the sixth switching device, the first end of the seventh switching device, the first end of the eleventh switching device, and the first end of the twelfth switching device is a grid of the NMOS tube, each of the second end of the fourth switching device, the second end of the fifth switching device, the second end of the sixth switching device, the second end of the seventh switching device, the second end of the eleventh switching device, and the second end of the twelfth switching device is a drain of the NMOS tube, and each of the third end of the fourth switching device, a third end of the third end of the fifth switching device, the third end of the sixth switching device, the third end of the seventh switching device, the third end of the eleventh switching device, and the third end of the twelfth switching device is a source of the NMOS tube.

Optionally, the signal detection apparatus further includes: a reference signal generation unit electrically connected with the amplification unit, and configured to generate the reference signal pair. The reference signal pair includes a first reference signal and a second reference signal. The reference signal generation unit includes an operational amplifier, a thirteenth switching device, a fourteenth switching device, a fifteenth switching device, a seventh impedance, an eighth impedance, a ninth impedance, and a tenth impedance. The fourteenth switching device and the fifteenth switching device are the same, and the ninth impedance and the tenth impedance are the same. A first end of the operational amplifier is used for inputting a third control voltage. A second end of the operational amplifier is respectively electrically connected with a first end of the eighth impedance, a first end of the ninth impedance, and a second end of the tenth impedance. A third end of the operational amplifier is electrically connected with a second end of the seventh impedance and a first end of the thirteenth switching device. A first end of the seventh impedance is electrically connected with a second end of the eighth impedance, a third end of the thirteenth switching device is used for inputting a supply voltage, a second end of the thirteenth switching device is electrically connected with a second end of the ninth impedance and used for outputting the first reference signal, and a first end of the fourteenth switching device is respectively electrically connected with a second end of the fourteenth switching device and a first end of the fifteenth switching device, and used for inputting a control current. A third end of the fourteenth switching device and a third end of the fifteenth switching device are electrically connected with the ground end, and a second end of the fifteenth switching device is electrically connected with a first end of the tenth impedance, and used for outputting the second reference signal.

Optionally, the thirteenth switching device is a PMOS tube, the fourteenth switching device and the fifteenth switching device are NMOS tubes, the seventh impedance, the ninth impedance, and the tenth impedance are resistors, and the eighth impedance is a capacitor; the first end of the thirteenth switching device is a grid of the PMOS tube, the second end of the thirteenth switching device is a drain of the PMOS tube, and the third end of the thirteenth switching device is a source of the PMOS tube; and each of the first end of the fourteenth switching device and the first end of the fifteenth switching device is a grid of the NMOS tube, each of the second end of the fourteenth switching device and the second end of the fifteenth switching device is a drain of the NMOS tube, and each of the third end of the fourteenth switching device and the third end of the fifteenth switching device is a source of the NMOS tube.

Optionally, the signal detection apparatus further includes: a signal processing unit, which is electrically connected with the amplification unit, and configured to process a second differential signal pair to obtain and output the first differential signal pair. The first differential signal pair includes a first differential signal and a second differential signal. The second differential signal pair includes a third differential signal and a fourth differential signal. The signal processing unit includes an eleventh impedance, a twelfth impedance, a thirteenth impedance, and a fourteenth impedance. A first end of the eleventh impedance is used for inputting the first differential signal, a second end of the eleventh impedance is electrically connected with a first end of the twelfth impedance, and used for outputting the third differential signal, a second end of the twelfth impedance is electrically connected with a first end of the thirteenth impedance, and used for inputting a third control voltage, a first end of the fourteenth impedance is used for inputting the second differential signal, and a second end of the thirteenth impedance is electrically connected with a second end of the fourteenth impedance, and used for outputting the fourth differential signal.

Optionally, the eleventh impedance and the fourteenth impedance are capacitors, and the twelfth impedance and the thirteenth impedance are resistors.

According to another aspect of this application, a re-driver is provided, and includes any signal detection apparatus.

### BRIEF DESCRIPTION OF THE DRAWINGS

Description drawings constituting a part of this application are used for providing further understanding of this application, and illustrative embodiments of this application and explanations thereof are used for explaining this application but do not improperly limit this application. In the drawings:

FIG. 1 is a structural block diagram of a signal detection apparatus according to an embodiment of this application;

FIG. 2 is a structural block diagram of an amplification unit according to an embodiment of this application;

FIG. 3 is a structural block diagram of a comparison unit according to an embodiment of this application.

FIG. 4 is a structural block diagram of a reference signal generation unit according to an embodiment of this application; and

FIG. 5 is a structural block diagram of signal processing according to an embodiment of this application.

The above figures include following reference numerals:

100—amplification unit; 101—first amplification component; 102—second amplification component; 103—first switching device; 104—second switching device; 105—third switching device; 106—first impedance; 107—second impedance; 200—comparison unit; 201—fourth switching device; 202—fifth switching device; 203—sixth switching device; 204—seventh switching device; 205—eighth switching device; 206—ninth switching device; 207—tenth switching device; 208—eleventh switching device; 209—twelfth switching device; 210—third impedance; 211—fourth impedance; 212—fifth impedance; 213—sixth impedance; 214—inverter; 300—reference signal generation unit; 301—operational amplifier; 302—thirteenth switching device; 303—fourteenth switching device; 304—fifteenth switching device; 305—seventh impedance; 306—eighth impedance; 307—ninth impedance; 308—tenth impedance; 400—signal processing unit; 401—eleventh impedance; 402—twelfth impedance; 403—thirteenth impedance; and 404—fourteenth impedance.

### DETAILED DESCRIPTION OF THE EMBODIMENTS

It should be noted that embodiments in this application and features in the embodiments can be mutually combined without conflicts. This application is described in detail in reference to the drawings and in combination with the embodiments as below.

To make those skilled in the art better understand solutions of this application, the technical solutions in the embodiments of this application are clearly and completely described by combining the drawings in the embodiments of this application as below, and it is apparent that the described embodiments are merely a part rather all embodiments of this application. Based on the embodiments of this application, all other embodiments obtained by those of ordinary skill in the art without creative labor shall fall within the scope of protection of this application.

It should be noted that terms such as “first” and “second” of description and claims of this application and the foregoing drawings are used for distinguishing similar objects but are not necessarily intended to describe specific sequences or precedence orders. It is to be understood that adopted data can be exchanged under a proper situation so as to implement the embodiments of this application described herein. In addition, terms “include” and “have” and any variations thereof are intended to encompass non-exclusive inclusions. For example, a process, method, system, product or device including a series of steps or units is not necessarily limited to those explicitly-listed steps or units, but may include other inexplicitly-listed steps or units or other inherent steps or units for the process, method, product or device.

As introduced in the background art, the performance of the high-speed signal detector in the prior art is influenced by PVT variations, and the detection threshold of the signal detector fluctuates within a wide range, exceeding the specified range, which can result in circuit functionality failure. In order to solve the above problem, an embodiment of this application provides a signal detection apparatus and a re-driver.

Technical solutions in embodiments of the present disclosure are clearly and completely described in combination with drawings in the embodiments of the present disclosure.

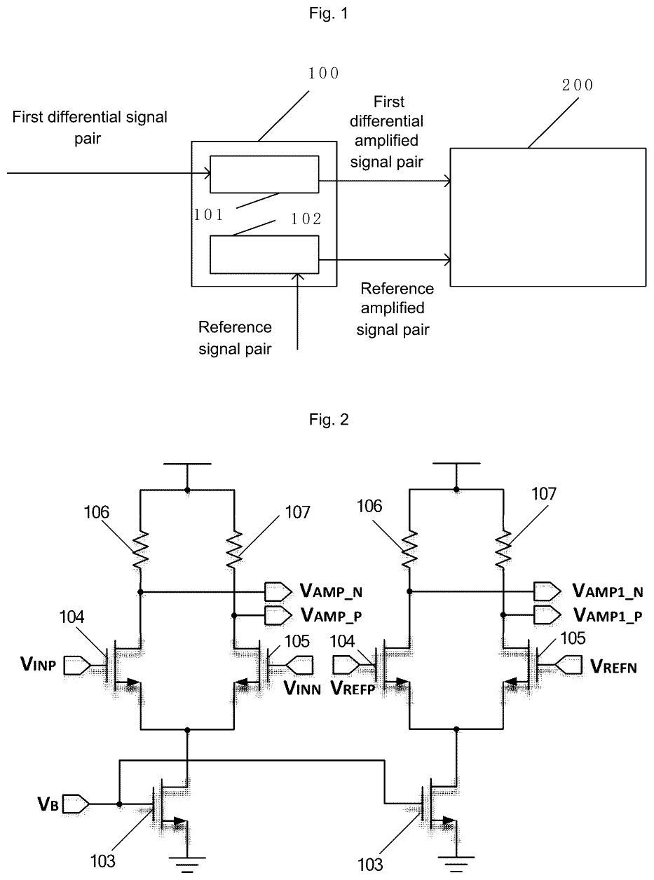

FIG. 1 is a structural block diagram of a signal detection apparatus according to an embodiment of this application. As shown in FIG. 1, the apparatus includes:
an amplification unit 100 and a comparison unit 200. A first end of the amplification unit 100 is used for inputting a first differential signal pair, and a second end of the amplification unit 100 is used for inputting a reference signal pair. The amplification unit 100 includes a first amplification component 101 and a second amplification component 102. The first amplification component 101 is configured to amplify the first differential signal pair to obtain a first differential amplified signal pair. The second amplification component 102 is configured to amplify the reference signal pair to obtain a reference amplified signal pair. A third end of the amplification unit 100 is used for outputting the first differential amplified signal pair and the reference amplified signal pair. The first differential amplified signal pair includes a first target signal and a second target signal. The reference amplified signal pair includes a first target reference signal and a second target reference signal. The first amplification component 101 and the second amplification component 102 are the same.

Specifically, the first differential signal pair received by the re-driver is transmitted by a long channel, causing that the amplitude of the first differential signal pair is attenuated to a great degree, and thus, the first amplification component 101 in the amplification unit is configured to amplify the first differential signal pair. To ensure that the gain of the first differential signal pair is the same as that of the reference signal pair and remains unaffected by PVT variations, the second amplification component 102 is configured to amplify the reference signal pair, and meanwhile, the first amplification component 101 and the second amplification component 102 are the same, which can achieve perfectly matched signal gain and reference voltage gain in the above signal detection apparatus.

The comparison unit 200 is electrically connected with the third end of the amplification unit 100, and is configured to compare the first target signal and a reference threshold and compare the second target signal and the reference threshold, and output a comparison result, where the reference threshold is a difference Value between the first target reference signal and the second target reference signal.

Specifically, if the first target signal or the second target signal greater than or equal to the above reference threshold is detected, a high level is output; and if the first target signal or the second target signal lower than the above reference threshold is detected, a low level is output. The first differential signal pair is detected.

According to this embodiment, the signal detection apparatus is provided. The apparatus includes the amplification unit and the comparison unit. The first end of the amplification unit is used for inputting the first differential signal pair, and the second end of the amplification unit is used for inputting the reference signal pair. The amplification unit includes the first amplification component and the second amplification component. The first amplification component is configured to amplify the first differential signal pair to obtain the first differential amplified signal pair. The second amplification component is configured to amplify the reference signal pair to obtain the reference amplified signal pair. The third end of the amplification unit is used for outputting the first differential amplified signal pair and the reference amplified signal pair. The first differential amplified signal pair includes the first target signal and the second target signal. The reference amplified signal pair includes the first target reference signal and the second target reference signal. The first amplification component and the second amplification component are the same. The comparison unit is electrically connected with the third end of the amplification unit, and is configured to respectively compare the relationships between the first target signal and the reference threshold and between the second target signal and the reference threshold, and output the comparison result. Because the amplification unit includes the first amplification component and the second amplification component which are completely the same, and provides a signal gain path and a reference voltage gain path which are completely and identically matched, thereby ensuring that the signals and the reference threshold are not influenced by variations of the process, voltage and temperature, and solving the problem that the existing high-speed signal detector is influenced by the process, voltage and temperature, resulting in inaccurate signal detection results.

In a specific implementation process, as shown in FIG. 2, the first amplification component and the second amplification component both include a first switching device 103, a second switching device 104, a third switching device 105, a first impedance 106, and a second impedance 107. The second switching device 104 and the third switching device 105 are the same. A first end of the first switching device 103 is used for inputting a first control voltage, and a second end of the first switching device 103 is respectively electrically connected with a third end of the second switching device 104 and a third end of the third switching device 105. A third end of the first switching device 103 is connected with a ground end, a second end of the second switching device 104 is electrically connected with a first end of the first impedance 106, and a second end of the third switching device 105 is electrically connected with a first end of the second impedance 107. A second end of the first impedance 106 is electrically connected with a second end of the second impedance 107. A first end of the second switching device 104 and a first end of the third switching device 105 of the first amplification component are used for inputting the first differential signal pair. A first end of the second switching device 104 and a first end of the third switching device 105 of the second amplification component are used for inputting the reference signal pair. The second end of the second switching device 104 and the second end of the third switching device 105 of the first amplification component are used for outputting the first differential amplified signal pair, and the second end of the second switching device 104 and the second end of the third switching device 105 of the second amplification component are used for outputting the reference amplified signal pair. By configuring the first amplification component and the second amplification component to maintain complete consistency in terms of transistor size, resistor load size, and current bias, the apparatus can further ensure that an amplification gain ratio of two sets of signals is 1:1, and the ratio is not influenced by PVT variations.

Specifically, the first amplification component for differential data signals and the second amplification component for amplifying reference voltage are kept completely consistent in terms of transistor size, resistor load size, and current bias, which ensures that the amplification gain ratio of the two sets of signals is 1:1, and the ratio is not influenced by PVT variations. V_{INP} and V_{INN} denote the first differential signal pair, V_{REFP} and V_{REFN} denote the reference signal pair, V_{AMP_P} and V_{AMP_N} denote the first differential amplified signal pair, V_{AMP1_P} and V_{AMP1_P} denote the reference amplified signal pair, and V_{B} denotes the first control voltage.

As shown in FIG. 2, the first switching device 103, the second switching device 104, and the third switching device 105 in this application are NMOS tubes, the first impedance 106 and the second impedance 107 are resistors, grids of the NMOS tubes are the first ends of the first switching device 103, the second switching device 104, and the third switching device 105, drains of the NMOS tubes are the second ends of the first switching device 103, the second switching device 104, and the third switching device 105, and sources of the NMOS tubes are the third ends of the first switching device 103, the second switching device 104, and the third switching device 105. The amplification unit of the apparatus may be further simplified.

Specifically, the first amplification component and the second amplification component actually adopt a current mode logic structure to amplify channel attenuated signals. Current mode logic (CML) is a high-speed metal-oxide-semiconductor (MOS) logic structure, and has a working principle that a logic gate is realized in the form of a differential transistor pair, sources of transistors serve as input, ground current serves as a low level, source current serves as a high level, and when the input is in the high level, the source current flows through the transistors towards a load, forming a high level output. Output is in a differential form, that is, two output levels are almost completely opposite, thereby reducing a space charge and an electromagnetic field.

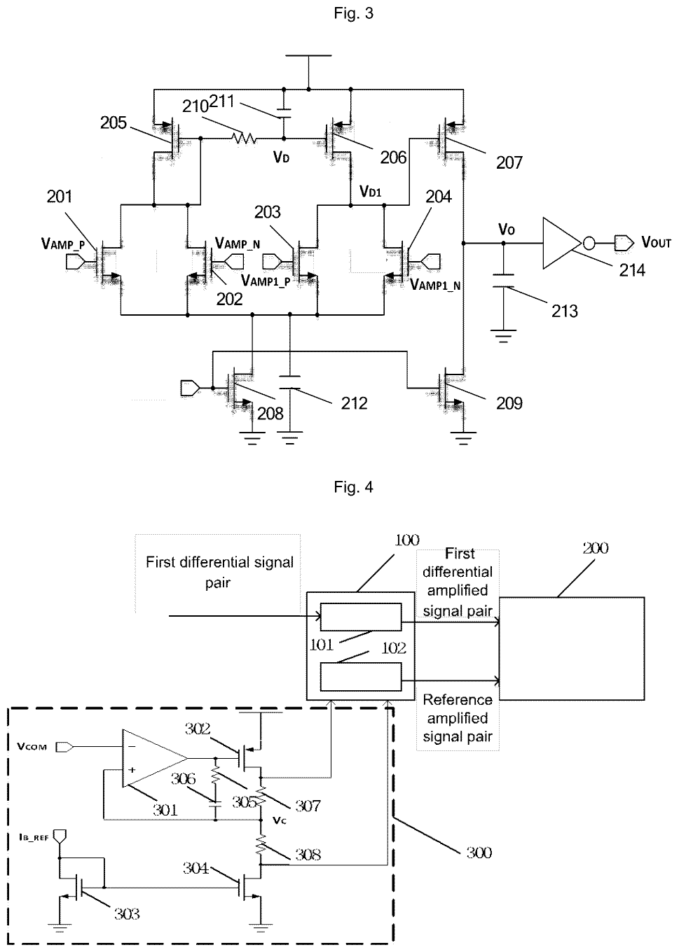

As shown in FIG. 3, the comparison unit includes a fourth switching device 201, a fifth switching device 202, a sixth switching device 203, a seventh switching device 204, an eighth switching device 205, a ninth switching device 206, a tenth switching device 207, an eleventh switching device 208, a twelfth switching device 209, a third impedance 210, a fourth impedance 211, a fifth impedance 212, a sixth impedance 213, and an inverter 214. The fourth switching device 201, the fifth switching device 202, the sixth switching device 203, and the seventh switching device 204 are the same. The eighth switching device 205 and the ninth switching device 206 are the same. A first end of the fourth switching device 201 and a first end of the fifth switching device 202 are used for inputting the first differential amplified signal pair. A second end of the fourth switching device 201 is respectively electrically connected with a second end of the fifth switching device 202, a first end and a second end of the eighth switching device 205, and a first end of the third impedance 210. A second end of the third impedance 210 is respectively electrically connected with a first end of the fourth impedance 211 and a first end of the ninth switching device 206. A third end of the eighth switching device 205 is respectively electrically connected with a second end of the fourth impedance 211, a third end of the ninth switching device 206, and a third end of the tenth switching device 207. A first end of the sixth switching device 203 and a first end of the seventh switching device 204 are used for inputting the reference amplified signal pair. A second end of the sixth switching device 203 is respectively electrically connected with a second end of the seventh switching device 204, a second end of the ninth switching device 206, and a first end of the tenth switching device 207. A third end of the fourth switching device 201 is respectively electrically connected with a third end of the fifth switching device 202, a third end of the sixth switching device 203, a third end of the seventh switching device 204, a second end of the eleventh switching device 208, and a first end of the fifth impedance 212. A first end of the eleventh switching device 208 and a first end of the twelfth switching device 209 are used for inputting a second control voltage. A third end of the eleventh switching device 208, a second end of the fifth impedance 212, a third end of the twelfth switching device 209, and a second end of the sixth impedance 213 are connected with the ground end, a second end of the twelfth switching device 209 is respectively electrically connected with a second end of the tenth switching device 207, a first end of the sixth impedance 213, and a first end of the inverter 214, and a second end of the inverter 214 is used for outputting the comparison result. The device can not only realize signal amplitude detection but also implement amplitude comparison, and the signal detection apparatus is simplified.

Specifically, the fourth switching device and the fifth switching device, as well as the sixth switching device and the seventh switching device, respectively constitute two rectifiers, output voltage V_{D} and V_{D1} of the rectifiers is correlated to input signal amplitude, and the first differential amplified signal pair and the reference amplified signal pair increase, V_{D} and V_{D1} decrease. If the reference threshold is set at a fixed value, the value of V_{D1} depends on the changes in V_{D}. V_{A} denotes the second control voltage, V_{AMP_P} and V_{AMP_N} denote the first differential amplified signal pair, V_{AMP1_P} and V_{AMP1_P} denote the reference amplified signal pair, and when the amplitude of V_{AMP_P} and V_{AMP_N} is increased, V_{D} is reduced, and V_{D1} is increased; and when the amplitude of the first differential amplified signal pair is greater than that of the reference amplified signal pair, V_{D1} passes through the eighth switching device and the ninth switching device to pull V_{O} down close to a ground line, and make Vₒᵤₜ output high. When the amplitude of the first differential amplified signal pair is reduced, V_{D} is increased, and V_{D1} is reduced; and when the amplitude of the first differential amplified signal pair is less than that of the reference amplified signal pair, V_{D1} passes through the eighth switching device and the ninth switching device to pull V_{O} up close to a power line, and make Vₒᵤₜ output low.

In some embodiments, as shown in FIG. 3, the eighth switching device 205, the ninth switching device 206 and the tenth switching device 207 are PMOS tubes, the fourth switching device 201, the fifth switching device 202, the sixth switching device 203, the seventh switching device 204, the eleventh switching device 208, and the twelfth switching device 209 are NMOS tubes, the third impedance 210 is a resistor, and the fourth impedance 211, the fifth impedance 212 and the sixth impedance 213 are capacitors. Grids of the PMOS tubes are the first ends of the eighth switching device 205, the ninth switching device 206, and the tenth switching device 207, drains of the PMOS tubes are the second ends of the eighth switching device 205, the ninth switching device 206, and the tenth switching device 207, and sources of the PMOS tubes are the third ends of the eighth switching device 205, the ninth switching device 206, and the tenth switching device 207. Grids of the NMOS tubes are the first ends of the fourth switching device 201, the fifth switching device 202, the sixth switching device 203, the seventh switching device 204, the eleventh switching device 208, and the twelfth switching device 209, drains of the NMOS tubes are the second ends of the fourth switching device 201, the fifth switching device 202, the sixth switching device 203, the seventh switching device 204, the eleventh switching device 208, and the twelfth switching device 209, and sources of the NMOS tubes are the third ends of the fourth switching device 201, the fifth switching device 202, the sixth switching device 203, the seventh switching device 204, the eleventh switching device 208, and the twelfth switching device 209. The comparison unit of the apparatus may be further simplified.

Specifically, the fourth switching device, the fifth switching device, the sixth switching device, and the seventh switching device constituting the rectifiers are kept consistent in size, the eighth switching device and the ninth switching device are kept consistent in size, and the gain of the differential signal gain and the reference voltage is kept at 1:1 under any PVT condition.

In some embodiments, as shown in FIG. 4, the signal detection apparatus further includes: a reference signal generation unit 300 electrically connected with the amplification unit, and configured to generate the reference signal pair. The reference signal pair includes a first reference signal and a second reference signal. The reference signal generation unit 300 includes an operational amplifier 301, a thirteenth switching device 302, a fourteenth switching device 303, a fifteenth switching device 304, a seventh impedance 305, an eighth impedance 306, a ninth impedance 307, and a tenth impedance 308. The fourteenth switching device 303 and the fifteenth switching device 304 are the same, and the ninth impedance 307 and the tenth impedance 308 are the same. A first end of the operational amplifier 301 is used for inputting a third control voltage. A second end of the operational amplifier 301 is respectively electrically connected with a first end of the eighth impedance 306, a first end of the ninth impedance 307, and a second end of the tenth impedance 308. A third end of the operational amplifier 301 is electrically connected with a second end of the seventh impedance 305 and a first end of the thirteenth switching device 302. A first end of the seventh impedance 305 is electrically connected with a second end of the eighth impedance 306, a third end of the thirteenth switching device 302 is used for inputting a supply voltage, a second end of the thirteenth switching device 302 is electrically connected with a second end of the ninth impedance 307 and used for outputting the first reference signal, and a first end of the fourteenth switching device 303 is respectively electrically connected with a second end of the fourteenth switching device 303 and a first end of the fifteenth switching device 304, and used for inputting a control current. A third end of the fourteenth switching device 303 and a third end of the fifteenth switching device 304 are electrically connected with the ground end, and a second end of the fifteenth switching device 304 is electrically connected with a first end of the tenth impedance 308, and used for outputting the second reference signal. The apparatus can rapidly generate the reference signal pair.

Specifically, if bias current is generated by a voltage-to-current converter, and reference voltage of the voltage-to-current converter is generated by a bandgap reference circuit, a proportional relationship between signal threshold voltage and the reference voltage of the voltage-to-current converter is determined by a proportional relationship between the resistors, and thus, the reference threshold will not be influenced by PVT variations.

In this embodiment, as shown in FIG. 4, the thirteenth switching device 302 is a PMOS tube, the fourteenth switching device 303 and the fifteenth switching device 304 are NMOS tubes, the seventh impedance 305, the ninth impedance 307, and the tenth impedance 308 are resistors, and the eighth impedance 306 is a capacitor. A grid of the PMOS tube is the first end of the thirteenth switching device 302, a drain of the PMOS tube is the second end of the thirteenth switching device 302, and a source of the PMOS tube is the third end of the thirteenth switching device 302. Grids of the NMOS tubes are the first ends of the fourteenth switching device 303 and the fifteenth switching device 304, drains of the NMOS tubes are the second ends of the fourteenth switching device 303 and the fifteenth switching device 304, and sources of the NMOS tubes are the third ends of the fourteenth switching device 303 and the fifteenth switching device 304. The reference signal generation unit of the apparatus may be further simplified.

Specifically, the operational amplifier, the thirteenth switching device and the ninth impedance constitute a negative feedback loop that the locks voltage V_{C} to the voltage V_{COM}, and I_{B_REF} denotes the control current. A ninth impedance value and a tenth impedance value are kept consistent, the fourteenth switching device and the fifteenth switching device are kept consistent in size, and thus, the reference threshold is generated by input bias current respectively in conjunction with the ninth impedance and the tenth impedance.

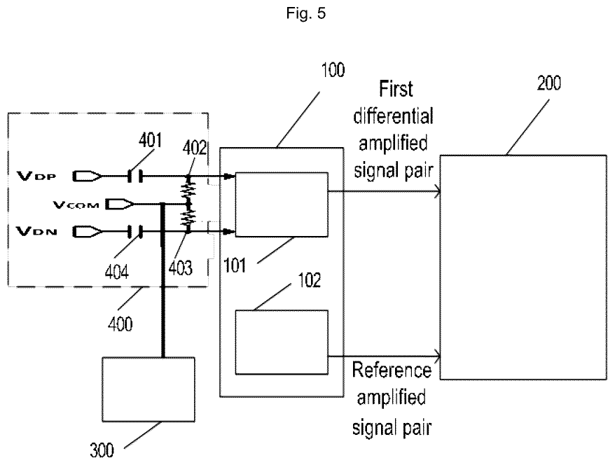

As an optional solution, as shown in FIG. 5, the signal detection apparatus further includes: a signal processing unit 400, which is electrically connected with the amplification unit, and configured to process a second differential signal pair to obtain and output the first differential signal pair. The first differential signal pair includes a first differential signal and a second differential signal. The second differential signal pair includes a third differential signal and a fourth differential signal. The signal processing unit 400 includes an eleventh impedance 401, a twelfth impedance 402, a thirteenth impedance 403, and a fourteenth impedance 404. A first end of the eleventh impedance 401 is used for inputting the first differential signal, a second end of the eleventh impedance 401 is electrically connected with a first end of the twelfth impedance 402, and used for outputting the third differential signal, a second end of the twelfth impedance 402 is electrically connected with a first end of the thirteenth impedance 403, and used for inputting a third control voltage, a first end of the fourteenth impedance 404 is used for inputting the second differential signal, and a second end of the thirteenth impedance 403 is electrically connected with a second end of the fourteenth impedance 404, and used for outputting the fourth differential signal. Because the second differential signal pair may not reach the operating voltage of the amplification unit, the apparatus may process the second differential signal pair before inputting the second differential signal pair into the amplification unit, thereby further satisfying the operating conditions of the amplification unit.

Specifically, the eleventh impedance, the twelfth impedance, the thirteenth impedance, and the fourteenth impedance may reconstruct the second differential signal pair. V_{DP} denotes the first differential signal, V_{DN} denotes the second differential signal, V_{COM} denotes the third control voltage, and the third control voltage may also be input to the reference signal generation unit 300.

As an optional solution shown in FIG. 5, the eleventh impedance 401 and the fourteenth impedance 404 are capacitors, and the twelfth impedance 402 and the thirteenth impedance 403 are resistors. The signal processing unit of the apparatus may be further simplified.

Specifically, the eleventh impedance and the fourteenth impedance are the capacitors to isolate direct current in the second differential signal pair, and the twelfth impedance and the thirteenth impedance are the resistors to process the second differential signal.

It should be noted that terms “include”, “include”, or any other variations thereof are intended to encompass non-exclusive inclusions, such that a process, method, product, or device including a series of elements not only includes those elements but also includes other elements not explicitly listed, or further includes inherent elements for the process, method, product or device. In the absence of further restrictions, the element specified by the phrase “including a. . . ” does not exclude the existence of other identical elements in the process, method, product, or device that includes the elements.

It can be inferred from the foregoing descriptions that the foregoing embodiments of this application realize following technical effects:
a. The signal detection apparatus in this application includes the amplification unit and the comparison unit. The first end of the amplification unit is used for inputting the first differential signal pair, and the second end of the amplification unit is used for inputting the reference signal pair. The amplification unit includes the first amplification component and the second amplification component. The first amplification component is configured to amplify the first differential signal pair to obtain the first differential amplified signal pair. The second amplification component is configured to amplify the reference signal pair to obtain the reference amplified signal pair. The third end of the amplification unit is used for outputting the first differential amplified signal pair and the reference amplified signal pair. The first differential amplified signal pair includes the first target signal and the second target signal. The reference amplified signal pair includes the first target reference signal and the second target reference signal. The first amplification component and the second amplification component are the same. The comparison unit is electrically connected with the third end of the amplification unit, and is configured to respectively compare the relationships between the first target signal and the reference threshold and between the second target signal and the reference threshold, and output the comparison result. Because the amplification unit includes the first amplification component and the second amplification component which are completely the same, and provides the signal gain path and the reference voltage gain path which are completely and identically matched, thereby ensuring that the signals and the reference threshold are not influenced by variations of the process, voltage and temperature, and solving the problem that the existing high-speed signal detector is influenced by the process, voltage and temperature, resulting in inaccurate signal detection results.
b. The re-driver in this application includes the signal detection apparatus. The signal detection apparatus includes the amplification unit and the comparison unit. The first end of the amplification unit is used for inputting the first differential signal pair, and the second end of the amplification unit is used for inputting the reference signal pair. The amplification unit includes the first amplification component and the second amplification component. The first amplification component is configured to amplify the first differential signal pair to obtain the first differential amplified signal pair. The second amplification component is configured to amplify the reference signal pair to obtain the reference amplified signal pair. The third end of the amplification unit is used for outputting the first differential amplified signal pair and the reference amplified signal pair. The first differential amplified signal pair includes the first target signal and the second target signal. The reference amplified signal pair includes the first target reference signal and the second target reference signal. The first amplification component and the second amplification component are the same. The comparison unit is electrically connected with the third end of the amplification unit, and is configured to respectively compare the relationships between the first target signal and the reference threshold and between the second target signal and the reference threshold, and output the comparison result. Because the amplification unit includes the first amplification component and the second amplification component which are completely the same, and provides the signal gain path and the reference voltage gain path which are completely and identically matched, thereby ensuring that the signals and the reference threshold are not influenced by variations of the process, voltage and temperature, and solving the problem that the high-speed signal detector of the existing re-driver is influenced by the process, voltage and temperature, resulting in inaccurate signal detection results.

The above embodiments are merely preferred embodiments of this application and are not used for limiting this application, and this application can be variously modified and changed for those skilled in the art. Any modification, equivalent replacement, improvement, etc. made within the spirit and the principle of this application shall fall within the scope of protection of this application.

1. A signal detection apparatus, comprising:
an amplification unit, wherein a first end of the amplification unit is used for inputting a first differential signal pair, a second end of the amplification unit is used for inputting a reference signal pair, the amplification unit comprises a first amplification component and a second amplification component, the first amplification component is configured to amplify the first differential signal pair to obtain a first differential amplified signal pair, the second amplification component is configured to amplify the reference signal pair to obtain a reference amplified signal pair, a third end of the amplification unit is used for outputting the first differential amplified signal pair and the reference amplified signal pair, the first differential amplified signal pair comprises a first target signal and a second target signal, the reference amplified signal pair comprises a first target reference signal and a second target reference signal, and the first amplification component and the second amplification component are the same; and
a comparison unit, electrically connected with the third end of the amplification unit, and configured to compare the first target signal and a reference threshold and compare the second target signal and the reference threshold, and output a comparison result, wherein the reference threshold is a difference Value between the first target reference signal and the second target reference signal.

2. The signal detection apparatus according to claim 1, wherein the first amplification component and the second amplification component respectively comprise a first switching device, a second switching device, a third switching device, a first impedance, and a second impedance; the second switching device and the third switching device are the same, a first end of the first switching device is used for inputting a first control voltage, and a second end of the first switching device is respectively electrically connected with a third end of the second switching device and a third end of the third switching device; a third end of the first switching device is connected with a ground end, a second end of the second switching device is electrically connected with a first end of the first impedance, and a second end of the third switching device is electrically connected with a first end of the second impedance; a second end of the first impedance is electrically connected with a second end of the second impedance; a first end of the second switching device of the first amplification component and a first end of the third switching device of the first amplification component are used for inputting the first differential signal pair; a first end of the second switching device of the second amplification component and a first end of the third switching device of the second amplification component are used for inputting the reference signal pair; and the second end of the second switching device of the first amplification component and the second end of the third switching device of the first amplification component are used for outputting the first differential amplified signal pair, and the second end of the second switching device of the second amplification component and the second end of the third switching device of the second amplification component are used for outputting the reference amplified signal pair.

3. The signal detection apparatus according to claim 2, wherein the first switching device, the second switching device, and the third switching device are N-Channel Metal Oxide Semiconductor (NMOS) tubes, the first impedance and the second impedance are resistors, each of the first end of the first switching device, the first end of the second switching device, and the first end of the third switching device is a grid of the NMOS tube, each of the second end of the first switching device, the second end of the second switching device, and the second end of the third switching device is a drain of the NMOS tube, and each of the third end of the first switching device, the third end of the second switching device, and the third end of the third switching device is a source of the NMOS tube.

4. The signal detection apparatus according to claim 1, wherein the comparison unit comprises a fourth switching device, a fifth switching device, a sixth switching device, a seventh switching device, an eighth switching device, a ninth switching device, a tenth switching device, an eleventh switching device, a twelfth switching device, a third impedance, a fourth impedance, a fifth impedance, a sixth impedance, and an inverter; the fourth switching device, the fifth switching device, the sixth switching device, and the seventh switching device are the same; the eighth switching device and the ninth switching device are the same; a first end of the fourth switching device and a first end of the fifth switching device are used for inputting the first differential amplified signal pair; a second end of the fourth switching device is respectively electrically connected with a second end of the fifth switching device, a first end and a second end of the eighth switching device, and a first end of the third impedance; a second end of the third impedance is respectively electrically connected with a first end of the fourth impedance and a first end of the ninth switching device; a third end of the eighth switching device is respectively electrically connected with a second end of the fourth impedance, a third end of the ninth switching device, and a third end of the tenth switching device; a first end of the sixth switching device and a first end of the seventh switching device are used for inputting the reference amplified signal pair; a second end of the sixth switching device is respectively electrically connected with a second end of the seventh switching device, a second end of the ninth switching device, and a first end of the tenth switching device; a third end of the fourth switching device is respectively electrically connected with a third end of the fifth switching device, a third end of the sixth switching device, a third end of the seventh switching device, a second end of the eleventh switching device, and a first end of the fifth impedance; a first end of the eleventh switching device and a first end of the twelfth switching device are used for inputting a second control voltage; a third end of the eleventh switching device, a second end of the fifth impedance, a third end of the twelfth switching device, and a second end of the sixth impedance are connected with the ground end, a second end of the twelfth switching device is respectively electrically connected with a second end of the tenth switching device, a first end of the sixth impedance, and a first end of the inverter, and a second end of the inverter is used for outputting the comparison result.

5. The signal detection apparatus according to claim 4, wherein the eighth switching device, the ninth switching device, and the tenth switching device are P-Channel Metal Oxide Semiconductor (PMOS) tubes, the fourth switching device, the fifth switching device, the sixth switching device, the seventh switching device, the eleventh switching device, and the twelfth switching device are NMOS tubes, the third impedance is a resistor, and the fourth impedance, the fifth impedance, and the sixth impedance are capacitors; each of a first end of the eighth switching device, the first end of the ninth switching device, and the first end of the tenth switching device is a grid of the PMOS tube, each of the second end of the eighth switching device, the second end of the ninth switching device, and the second end of the tenth switching device is a drain of the PMOS tube, and each of the third end of the eighth switching device, the third end of the ninth switching device, and a third end of the tenth switching device is a source of the PMOS tube; each of the first end of the fourth switching device, the first end of the fifth switching device, the first end of the sixth switching device, the first end of the seventh switching device, the first end of the eleventh switching device, and the first end of the twelfth switching device is a grid of the NMOS tube, each of the second end of the fourth switching device, the second end of the fifth switching device, the second end of the sixth switching device, the second end of the seventh switching device, the second end of the eleventh switching device, and the second end of the twelfth switching device is a drain of the NMOS tube, and each of the third end of the fourth switching device, a third end of the third end of the fifth switching device, the third end of the sixth switching device, the third end of the seventh switching device, the third end of the eleventh switching device, and the third end of the twelfth switching device is a source of the NMOS tube.

6. The signal detection apparatus according to claim 1, further comprising:
a reference signal generation unit, electrically connected with the amplification unit, and configured to generate the reference signal pair, wherein the reference signal pair comprises a first reference signal and a second reference signal, and the reference signal generation unit comprises an operational amplifier, a thirteenth switching device, a fourteenth switching device, a fifteenth switching device, a seventh impedance, an eighth impedance, a ninth impedance, and a tenth impedance; the fourteenth switching device and the fifteenth switching device are the same, and the ninth impedance and the tenth impedance are the same; a first end of the operational amplifier is used for inputting a third control voltage, a second end of the operational amplifier is respectively electrically connected with a first end of the eighth impedance, a first end of the ninth impedance, and a second end of the tenth impedance, and a third end of the operational amplifier is electrically connected with a second end of the seventh impedance and a first end of the thirteenth switching device; a first end of the seventh impedance is electrically connected with a second end of the eighth impedance, a third end of the thirteenth switching device is used for inputting a supply voltage, a second end of the thirteenth switching device is electrically connected with a second end of the ninth impedance and used for outputting the first reference signal, and a first end of the fourteenth switching device is respectively electrically connected with a second end of the fourteenth switching device and a first end of the fifteenth switching device, and used for inputting a control current; a third end of the fourteenth switching device and a third end of the fifteenth switching device are electrically connected with the ground end, and a second end of the fifteenth switching device is electrically connected with a first end of the tenth impedance, and used for outputting the second reference signal.

7. The signal detection apparatus according to claim 6, wherein the thirteenth switching device is a PMOS tube, the fourteenth switching device and the fifteenth switching device are NMOS tubes, the seventh impedance, the ninth impedance, and the tenth impedance are resistors, and the eighth impedance is a capacitor; the first end of the thirteenth switching device is a grid of the PMOS tube, the second end of the thirteenth switching device is a drain of the PMOS tube, and the third end of the thirteenth switching device is a source of the PMOS tube; and each of the first end of the fourteenth switching device and the first end of the fifteenth switching device is a grid of the NMOS tube, each of the second end of the fourteenth switching device and the second end of the fifteenth switching device is a drain of the NMOS tube, and each of the third end of the fourteenth switching device and the third end of the fifteenth switching device is a source of the NMOS tube.

8. The signal detection apparatus according to claim 1, further comprising:
a signal processing unit, electrically connected with the amplification unit, and configured to process a second differential signal pair to obtain and output the first differential signal pair, wherein the first differential signal pair comprises a first differential signal and a second differential signal, and the second differential signal pair comprises a third differential signal and a fourth differential signal; and the signal processing unit comprises an eleventh impedance, a twelfth impedance, a thirteenth impedance, and a fourteenth impedance, a first end of the eleventh impedance is used for inputting the first differential signal, a second end of the eleventh impedance is electrically connected with a first end of the twelfth impedance, and used for outputting the third differential signal, a second end of the twelfth impedance is electrically connected with a first end of the thirteenth impedance, and used for inputting a third control voltage, a first end of the fourteenth impedance is used for inputting the second differential signal, and a second end of the thirteenth impedance is electrically connected with a second end of the fourteenth impedance, and used for outputting the fourth differential signal.

9. The signal detection apparatus according to claim 8, wherein the eleventh impedance and the fourteenth impedance are capacitors, and the twelfth impedance and the thirteenth impedance are resistors.

10. A re-driver, comprising a signal detection apparatus, wherein the signal detection apparatus comprises:
an amplification unit, wherein a first end of the amplification unit is used for inputting a first differential signal pair, a second end of the amplification unit is used for inputting a reference signal pair, the amplification unit comprises a first amplification component and a second amplification component, the first amplification component is configured to amplify the first differential signal pair to obtain a first differential amplified signal pair, the second amplification component is configured to amplify the reference signal pair to obtain a reference amplified signal pair, a third end of the amplification unit is used for outputting the first differential amplified signal pair and the reference amplified signal pair, signal, the reference amplified signal pair comprises a first target reference signal and a second target reference signal, and the first amplification component and the second amplification component are the same; and
a comparison unit, electrically connected with the third end of the amplification unit, and configured to compare the first target signal and a reference threshold and compare the second target signal and the reference threshold, and output a comparison result, wherein the reference threshold is a difference value between the first target reference signal and the second target reference signal.

11. The re-driver according to claim 10, wherein the first amplification component and the second amplification component respectively comprise a first switching device, a second switching device, a third switching device, a first impedance, and a second impedance; the second switching device and the third switching device are the same; a first end of the first switching device is used for inputting a first control voltage, and a second end of the first switching device is respectively electrically connected with a third end of the second switching device and a third end of the third switching device; a third end of the first switching device is connected with a ground end, a second end of the second switching device is electrically connected with a first end of the first impedance, and a second end of the third switching device is electrically connected with a first end of the second impedance; a second end of the first impedance is electrically connected with a second end of the second impedance; a first end of the second switching device of the first amplification component and a first end of the third switching device of the first amplification component are used for inputting the first differential signal pair; a first end of the second switching device of the second amplification component and a first end of the third switching device of the second amplification component are used for inputting the reference signal pair; and the second end of the second switching device of the first amplification component and the second end of the third switching device of the first amplification component are used for outputting the first differential amplified signal pair, and the second end of the second switching device of the second amplification component and the second end of the third switching device of the second amplification component are used for outputting the reference amplified signal pair.

12. The re-driver according to claim 11, wherein the first switching device, the second switching device, and the third switching device are N-Channel Metal Oxide Semiconductor (NMOS) tubes, the first impedance and the second impedance are resistors, each of the first end of the first switching device, the first end of the second switching device, and the first end of the third switching device is a grid of the NMOS tube, each of the second end of the first switching device, the second end of the second switching device, and the second end of the third switching device is a drain of the NMOS tube, and each of the third end of the first switching device, the third end of the second switching device, and the third end of the third switching device is a source of the NMOS tube.

13. The re-driver according to claim 10, wherein the comparison unit comprises a fourth switching device, a fifth switching device, a sixth switching device, a seventh switching device, an eighth switching device, a ninth switching device, a tenth switching device, an eleventh switching device, a twelfth switching device, a third impedance, a fourth impedance, a fifth impedance, a sixth impedance, and an inverter; the fourth switching device, the fifth switching device, the sixth switching device, and the seventh switching device are the same; the eighth switching device and the ninth switching device are the same; a first end of the fourth switching device and a first end of the fifth switching device are used for inputting the first differential amplified signal pair; a second end of the fourth switching device is respectively electrically connected with a second end of the fifth switching device, a first end and a second end of the eighth switching device, and a first end of the third impedance; a second end of the third impedance is respectively electrically connected with a first end of the fourth impedance and a first end of the ninth switching device; a third end of the eighth switching device is respectively electrically connected with a second end of the fourth impedance, a third end of the ninth switching device, and a third end of the tenth switching device; a first end of the sixth switching device and a first end of the seventh switching device are used for inputting the reference amplified signal pair; a second end of the sixth switching device is respectively electrically connected with a second end of the seventh switching device, a second end of the ninth switching device, and a first end of the tenth switching device; a third end of the fourth switching device is respectively electrically connected with a third end of the fifth switching device, a third end of the sixth switching device, a third end of the seventh switching device, a second end of the eleventh switching device, and a first end of the fifth impedance; a first end of the eleventh switching device and a first end of the twelfth switching device are used for inputting a second control voltage; a third end of the eleventh switching device, a second end of the fifth impedance, a third end of the twelfth switching device, and a second end of the sixth impedance are connected with the ground end, a second end of the twelfth switching device is respectively electrically connected with a second end of the tenth switching device, a first end of the sixth impedance, and a first end of the inverter, and a second end of the inverter is used for outputting the comparison result.

14. The re-driver according to claim 13, wherein the eighth switching device, the ninth switching device, and the tenth switching device are P-Channel Metal Oxide Semiconductor (PMOS) tubes, the fourth switching device, the fifth switching device, the sixth switching device, the seventh switching device, the eleventh switching device, and the twelfth switching device are NMOS tubes, the third impedance is a resistor, and the fourth impedance, the fifth impedance, and the sixth impedance are capacitors; each of a first end of the eighth switching device, the first end of the ninth switching device, and the first end of the tenth switching device is a grid of the PMOS tube, each of the second end of the eighth switching device, the second end of the ninth switching device, and the second end of the tenth switching device is a drain of the PMOS tube, and each of the third end of the eighth switching device, the third end of the ninth switching device, and a third end of the tenth switching device is a source of the PMOS tube; each of the first end of the fourth switching device, the first end of the fifth switching device, the first end of the sixth switching device, the first end of the seventh switching device, the first end of the eleventh switching device, and the first end of the twelfth switching device is a grid of the NMOS tube, each of the second end of the fourth switching device, the second end of the fifth switching device, the second end of the sixth switching device, the second end of the seventh switching device, the second end of the eleventh switching device, and the second end of the twelfth switching device is a drain of the NMOS tube, and each of the third end of the fourth switching device, a third end of the third end of the fifth switching device, the third end of the sixth switching device, the third end of the seventh switching device, the third end of the eleventh switching device, and the third end of the twelfth switching device is a source of the NMOS tube.

15. The re-driver according to claim 10, further comprising:
a reference signal generation unit, electrically connected with the amplification unit, and configured to generate the reference signal pair, wherein the reference signal pair comprises a first reference signal and a second reference signal, and the reference signal generation unit comprises an operational amplifier, a thirteenth switching device, a fourteenth switching device, a fifteenth switching device, a seventh impedance, an eighth impedance, a ninth impedance, and a tenth impedance; the fourteenth switching device and the fifteenth switching device are the same, and the ninth impedance and the tenth impedance are the same; a first end of the operational amplifier is used for inputting a third control voltage, a second end of the operational amplifier is respectively electrically connected with a first end of the eighth impedance, a first end of the ninth impedance, and a second end of the tenth impedance, and a third end of the operational amplifier is electrically connected with a second end of the seventh impedance and a first end of the thirteenth switching device; a first end of the seventh impedance is electrically connected with a second end of the eighth impedance, a third end of the thirteenth switching device is used for inputting a supply voltage, a second end of the thirteenth switching device is electrically connected with a second end of the ninth impedance and used for outputting the first reference signal, and a first end of the fourteenth switching device is respectively electrically connected with a second end of the fourteenth switching device and a first end of the fifteenth switching device, and used for inputting a control current; a third end of the fourteenth switching device and a third end of the fifteenth switching device are electrically connected with the ground end, and a second end of the fifteenth switching device is electrically connected with a first end of the tenth impedance, and used for outputting the second reference signal.

16. The re-driver according to claim 15, wherein the thirteenth switching device is a PMOS tube, the fourteenth switching device and the fifteenth switching device are NMOS tubes, the seventh impedance, the ninth impedance, and the tenth impedance are resistors, and the eighth impedance is a capacitor; the first end of the thirteenth switching device is a grid of the PMOS tube, the second end of the thirteenth switching device is a drain of the PMOS tube, and the third end of the thirteenth switching device is a source of the PMOS tube; and each of the first end of the fourteenth switching device and the first end of the fifteenth switching device is a grid of the NMOS tube, each of the second end of the fourteenth switching device and the second end of the fifteenth switching device is a drain of the NMOS tube, and each of the third end of the fourteenth switching device and the third end of the fifteenth switching device is a source of the NMOS tube.

17. The re-driver according to claim 10, further comprising:
a signal processing unit, electrically connected with the amplification unit, and configured to process a second differential signal pair to obtain and output the first differential signal pair, wherein the first differential signal pair comprises a first differential signal and a second differential signal, and the second differential signal pair comprises a third differential signal and a fourth differential signal; and the signal processing unit comprises an eleventh impedance, a twelfth impedance, a thirteenth impedance, and a fourteenth impedance, a first end of the eleventh impedance is used for inputting the first differential signal, a second end of the eleventh impedance is electrically connected with a first end of the twelfth impedance, and used for outputting the third differential signal, a second end of the twelfth impedance is electrically connected with a first end of the thirteenth impedance, and used for inputting a third control voltage, a first end of the fourteenth impedance is used for inputting the second differential signal, and a second end of the thirteenth impedance is electrically connected with a second end of the fourteenth impedance, and used for outputting the fourth differential signal.

18. The re-driver according to claim 17, wherein the eleventh impedance and the fourteenth impedance are capacitors, and the twelfth impedance and the thirteenth impedance are resistors.
